(19) United States
(12) Patent Application Publication
(10) Pub. No.: US 2019/0139881 A1
(43) Pub. Date: May 9, 2019

(54) SECURITY DEVICE SUCH THAT A SMART CARD

(71) Applicant: IDEMIA France, Courbevoie (FR)

(72) Inventors: Olivier BOSQUET, Courbevoie (FR); Lucien AMIOT, Courbevoie (FR); Philippe LENCOU, Courbevoie (FR)

(21) Appl. No.: 16/181,643

(22) Filed: Nov. 6, 2018

(30) Foreign Application Priority Data
Nov. 8, 2017 (FR) 1760508

(51) Int. Cl. H01L 23/498; H01L 23/13; H01L 21/48; G06K 19/07

(52) U.S. Cl. CPC H01L 23/49855; H01L 23/49838; H01L 23/49833; H01L 24/48; H01L 23/13; H01L 21/4853; G06K 19/0723; H01L 23/49811

(57) ABSTRACT

A security device includes a body and a contact interface including an external connection for external communication and an internal connection for internal communication. The body includes at least a first substrate and a second substrate lying in respective parallel planes. The contact interface is electrically connected to the first substrate and to the second substrate by the internal connection. The security device is a chip card, for example a bank card, or an identity document.

The present invention relates to a security device such as a chip card, for example a bank or identity document card.

A chip card includes a card carrier or body and at least one electronic circuit. The electronic circuit is for example an integrated circuit for making secure payments or storing identity data.

For the integrated circuit to communicate with the outside, it includes a contact interface and/or contactless communication means, such as an antenna that is electrically connected to the integrated circuit.

Thus, the integrated circuit is able to communicate with the outside through the contact interface being brought into contact with a device suitable for this type of communication, this type of communication being known as communication with contact (for example such as defined by ISO standard 7816-2), or through the antenna, this type of communication being known as contactless communication (for example according to the ISO standard 14443 or NFC/ISO standard 15693). The card body defines the format of the chip card and is often formed of a plurality of layers, substrates or inlays that are arranged between two plastic layers which form respective outer faces of the body.

Layers are used to incorporate electronic components forming additional outside interfaces within the card body, which components are referred to below as electronic interface components.

Cavities are made in the layers for the placement of the electronic components therein.

Chip cards in which the contact interface opens out onto an outer face of the card body, and at least one electronic component, such as a display, a fingerprint reader, a button, a light sensor, a light-emitting diode (LED), a buzzer or a Bluetooth communication component, among others, forms an additional outside interface, are known. These additional interfaces may or may not be flush with the outer face of the card body depending on the chip card model.

In a known type of chip card, a module formed by the contact interface and the integrated circuit mounted on an inner face of the contact interface is located in an interface cavity made in the card body, the contact interface being flush with the outer face of the card body, i.e. being at the same level as the outer face of the body.

Chip cards in which the electronic interface component (other than the contact interface of the chip card) is mounted on a flexible printed circuit (FPC) are known. This printed circuit includes in particular control means, such as a microcontroller managing the operation of the electronic interface component, energy storage means, and an additional means for communicating with the outside, such as an antenna.

The flexible printed circuit constitutes a layer, substrate or inlay in this type of chip card.

Current chip cards generally include an antenna allowing the integrated circuit to communicate contactlessly with the outside. The antenna is formed on a layer, substrate or inlay other than the layer formed by the printed circuit and referred to below as the antenna inlay. The antenna is connected to the integrated circuit such that the integrated circuit is able to communicate with the outside through the antenna.

Once a chip card has been manufactured, it must be personalized. The personalization operations are distinct for the integrated circuit and for the electronic interface component.

In the type of chip card described above, the integrated circuit may be personalized by contact through the contact interface, or contactlessly through the antenna inlay. With regard to the electronic interface component on the printed circuit, personalization is carried out contactlessly through the antenna placed on the printed circuit.

Thus, the operations of personalizing this type of card are carried out either by means of two readers, one for communication with contact and the other for contactless communication, or by means of a reader capable of both communication with contact and contactless communication.

Additionally, it has been determined that when the integrated circuit is personalized by contact, and when the electronic component on the printed circuit is personalized contactlessly, personalization efficiency is decreased.

Furthermore, when the integrated circuit and the electronic component in the printed circuit are personalized contactlessly, the time needed for personalization increases substantially.

Another type of chip card, in which the integrated circuit and the electronic interface component are both mounted on the printed circuit, i.e. they are both mounted on a single substrate, is known. This type of card generally includes an antenna allowing the integrated circuit to communicate contactlessly with the outside. This antenna is formed on the same substrate as the integrated circuit and the electronic interface component, and is electrically connected to the integrated circuit.

In this type of chip card, the printed circuit and the contact interface are mechanically and electrically connected by means of solder bumps. Since the contact interface is electrically connected to the printed circuit, it may be electrically connected to any electronic component mounted on the printed circuit. Such a chip card, whether it involves the integrated circuit or other electronic components, may be personalized by contact through the contact interface. Thus, the efficiency of and the time taken for personalization are improved with respect to the preceding type of chip card.

However, the mounting and the production of these electronic components (the integrated circuit, the optional antenna for allowing the integrated circuit to communicate contactlessly with the outside and the electronic interface component) on a single layer, substrate or inlay specializes the latter for a specific range of chip cards. The stocks of layers are therefore specific and varied, which complicates the management thereof for manufacturing the chip cards.

The object of the present invention is to minimize the aforementioned drawbacks, and to provide a security device such as a chip card allowing the constraints related to the manufacture and personalization thereof to be decreased.

To this end, the present invention provides, according to a first aspect, a security device including a body and a contact interface that is mounted in the body, the contact interface including external connection means for communication outside the security device and internal connection means for communication inside the security device, the body including at least a first substrate and a second substrate lying in parallel planes, respectively, and including at least a first electronic component and a second electronic component, respectively.

According to the invention, the contact interface is electrically connected to said at least a first electronic component and a second electronic component of said at least a first substrate and a second substrate, respectively, by means of the internal connection means.

Thus, the contact interface is connected to at least one electrical component in each substrate.

When the body includes two substrates, a first substrate including at least a first electronic component and a second substrate including at least a second electronic component, the contact interface is electrically connected to the first and second electronic components in the first substrate and the second substrate, respectively.

It should be noted that when the body includes other substrates with at least one electronic component (for example a third substrate including a third electronic component), the contact interface is also connected to the electronic components in the other substrates.

Consequently, the electronic components that are mounted on the substrates communicating with the contact interface via internal connection means may communicate outside the security device through the contact interface.

In other words, for example when the body includes two substrates, the first and second electronic components, or other electronic components in the substrates that are connected thereto, may communicate with the outside by means of the contact interface, this communication thus taking place by contact.

Thus, only communication with contact may be used for communication between the electronic components of the substrates and the outside, making it possible to improve the speed of execution and the efficiency of the personalization process.

Furthermore, the electronic components in different substrates (for example the first and second electronic components) are able to communicate with one another by means of the contact interface, this allowing the security device to be implemented more flexibly, as long as the electronic components are able to be mounted in one or other substrate according to the architectures of the security devices, and as long as various types of electronic components may be combined in the production of the security devices. Consequently, the stock of manufactured security devices and of substrates can be managed more easily.

According to one feature, the contact interface includes an outer face that is flush with an outer face of said body and an inner face, the external connection means of said contact interface being arranged on the outer face, and the internal connection means of the contact interface being arranged on the inner face.

According to one feature, the security device further includes an integrated circuit that is mounted on the inner face of the contact interface and electrically connected to at least a portion of the external and internal connection means of the contact interface.

Thus, since the integrated circuit is mounted on the inner face of the contact interface and electrically connected to the contact interface, it is able to communicate outside the security device through the contact interface, i.e. by contact.

Furthermore, the first and second electronic components on the first and second substrates, respectively, are connected to the integrated circuit via the contact interface, these three elements being able to communicate with one another.

According to other embodiments, the integrated circuit is mounted on at least one of the substrates.

According to one feature, the internal connection means include at least a first internal connector and a second internal connector, the first internal connector connecting the contact interface to said first electronic component of the first substrate, and the second internal connector connecting the contact interface to said second electronic component of the second substrate.

The internal connection means may include additional internal connectors, which may connect the contact interface to electronic components in additional substrates. For example, a third internal connector may connect a third electronic component in a third substrate.

The contact interface is located in proximity to the first substrate and as such a conductive film is enough to connect the contact interface to said at least a first electronic component of the first substrate.

According to one feature, the security device includes an anisotropic conductive film that is positioned between the inner face of the contact interface and the first substrate.

The thickness of the anisotropic conductive film is such that the contact interface and the first substrate are both mechanically and electrically connected to one another.

According to one feature, at least the second substrate includes a zone of overlap that is arranged facing at least a portion of the internal connection means of the contact interface.

Thus, a portion of the contact interface is located facing a portion of the second substrate.

For example, the body may comprise other substrates with a zone of overlap that is arranged facing at least a portion of the internal connection means of the contact interface.

In one embodiment, the zone of overlap is arranged facing the second internal conductor of the contact interface.

According to another feature, the security device includes at least one solder ball connecting said at least a portion of the internal connection means of the contact interface to said second electronic component of the second substrate at the zone of overlap.

The solder ball is thus located between the inner face of the contact interface and the zone of overlap of the second substrate, and allows the space between the contact interface and the second substrate to be filled and the electrical connection between the contact interface and said at least a second electronic component in the second substrate to be formed.

It should be noted that the substrates are located in parallel planes, one of the substrates being located closer to the module than the other. The proximity of the substrate to the module depends on the thickness of the electronic components that are mounted on the substrates. Specifically, the arrangement of the substrates between the outer faces of the body is subject to constraints due to the thickness of the security device.

In one embodiment, the first substrate is located closer to the contact interface than the second substrate. As mentioned above, a conductive film is enough to connect the module to the first substrate.

Regarding the second substrate, which is arranged further away, at least one solder ball is used to form the connection between the contact interface and the second substrate.

Were the body to comprise a third substrate, at least one solder ball would also be used to form the connection between the contact interface and the third substrate.

According to one feature, the security device includes an anisotropic conductive film that is positioned between said portion of the internal connection means of the contact interface and said at least one solder ball.

The thickness of the anisotropic conductive film is such that the contact interface and the second substrate are thus both mechanically and electrically connected to one another.

According to one feature, the first electronic component is an antenna.

Thus, the contact interface is connected to an antenna via an anisotropic conductive film.

When an integrated circuit is mounted on and electrically connected to the contact interface, the integrated circuit is connected to an antenna via an anisotropic conductive film. The integrated circuit is thus able to communicate with the outside contactlessly, via this antenna, and by contact via the contact interface.

It should be noted that since an antenna is very thin, the first substrate may be arranged in proximity to the contact interface.

According to one feature, the second substrate is a printed circuit.

Thus, the contact interface is electrically connected to the printed circuit via solder balls and an anisotropic conductive film. The solder balls allow the distance between the contact interface and the printed circuit to be filled, this distance being due to the electronic components that are mounted on the printed circuit and to the optional flexibility of said printed circuit. Specifically, the thickness of the electronic components that are mounted on a printed circuit is such that the second substrate must be positioned a certain distance away with respect to the contact interface and to the outer face of the body onto which the contact interface opens out.

According to one feature, the first substrate includes at least one substrate cavity into which at least a portion of said second substrate is inserted.

According to a second aspect, the invention relates to a process for manufacturing a security device including a body and a contact interface, the body including at least a first substrate and a second substrate lying in respective parallel planes, and including at least a first electronic component and a second electronic component, respectively, the contact interface including external connection means for communication outside the security device and internal connection means for communication inside the security device, the manufacturing process including:

positioning the first substrate and the second substrate between outer layers of the body; and

positioning the contact interface in the body.

According to the invention, the manufacturing process further includes the implementation of an electrical connection from the contact interface to said at least a first electronic component and a second electronic component of said at least a first substrate and a second substrate, respectively, by means of the internal connection means.

According to one feature, the manufacturing process includes positioning an integrated circuit on an inner face of the contact interface and electrically connecting the integrated circuit to at least a portion of the external and internal connection means of the contact interface.

According to one feature, the manufacturing process includes forming at least one substrate cavity in the first substrate, which cavity is designed to accept at least a portion of the second substrate.

For example, the manufacturing process includes forming at least one substrate cavity that is designed to accept said at least a second electronic component of said second substrate.

In one embodiment, the manufacturing process includes forming a plurality of substrate cavities, each substrate cavity being designed to accept a portion of the second substrate, such as an electronic component mounted on the second substrate.

According to one feature, said at least one substrate cavity includes the entirety of the second substrate. According to one feature, before positioning the second substrate between the outer layers of the body, the manufacturing process includes positioning at least one solder ball on the second substrate.

According to one feature, the manufacturing process further includes positioning an anisotropic conductive film between the contact interface and the first and second substrates.

For example, the anisotropic conductive film takes the shape of a crown surrounding the integrated circuit.

The features and advantages of the process for manufacturing a security device are analogous to those described above in relation to the security device.

Other features and advantages of the invention will become further apparent in the following description.

In the appended drawings, which are provided by way of nonlimiting examples:

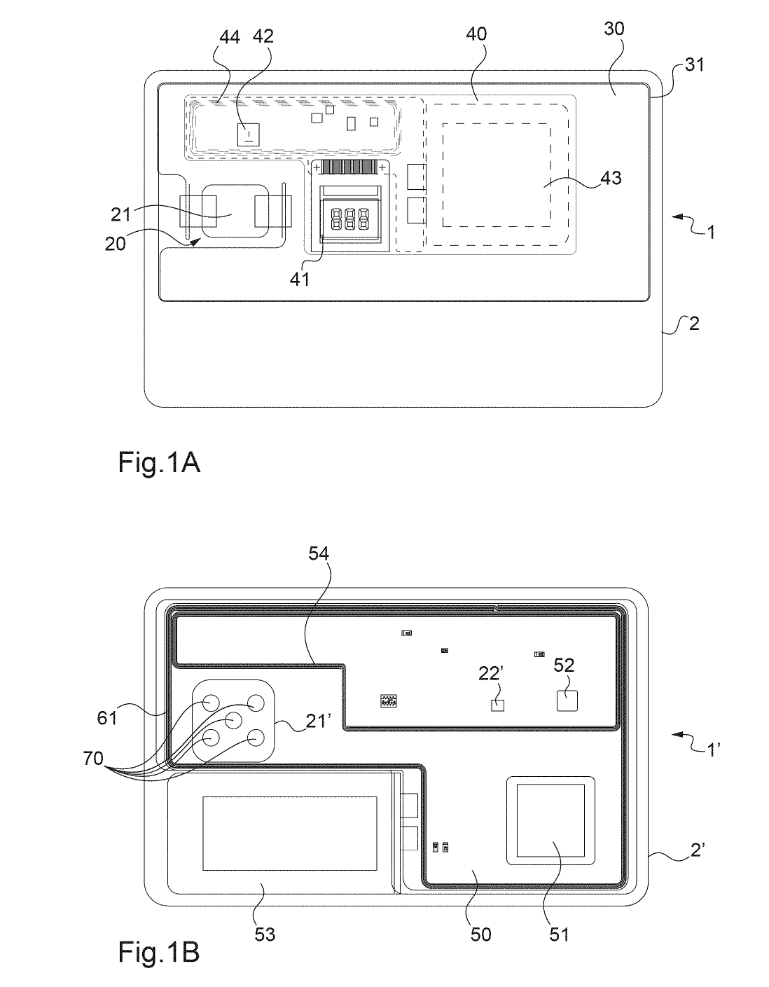

FIGS. 1A and 1B schematically show chip cards of the prior art;

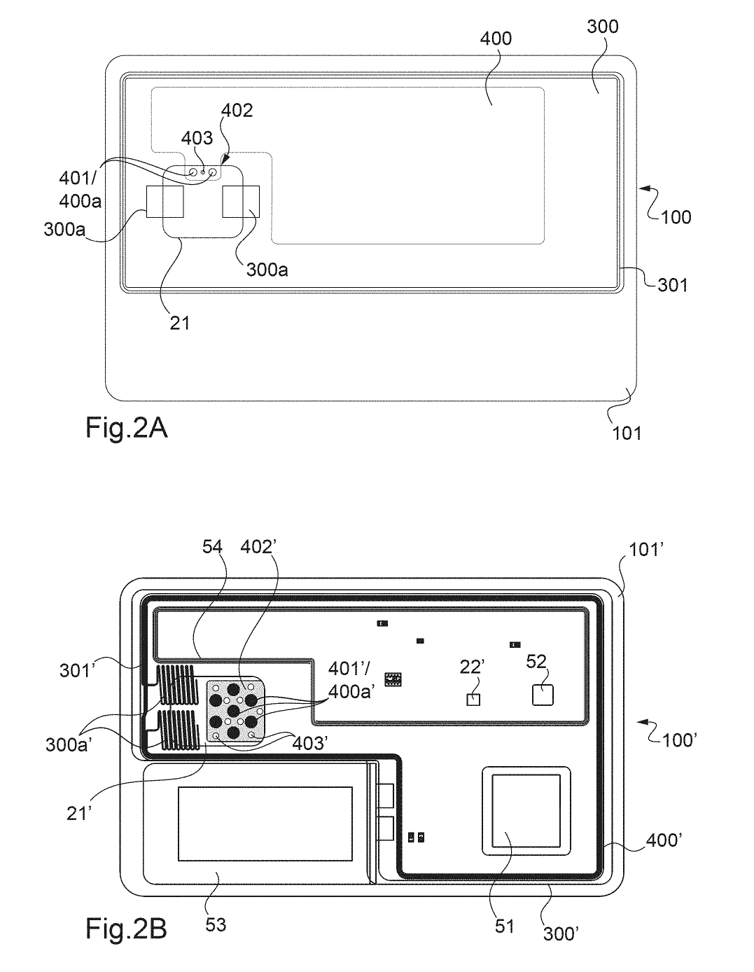

FIG. 2A schematically shows a chip card according to a first embodiment of the invention;

FIG. 2B schematically shows a chip card according to a second embodiment of the invention;

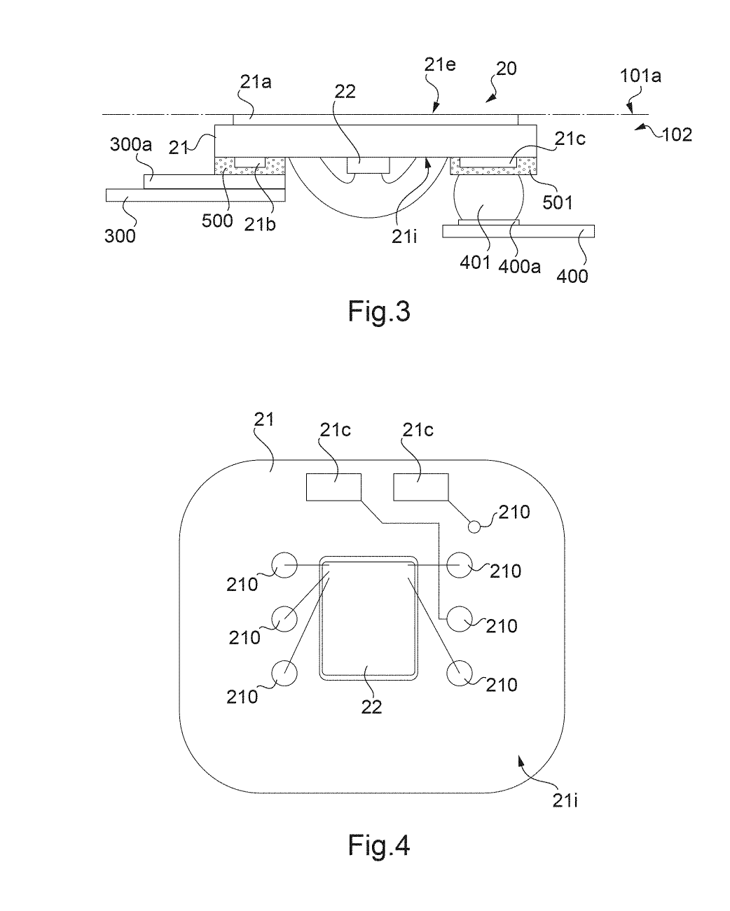

FIG. 3 is a partial sectional view of a chip card according to the embodiment shown in FIG. 2A; and

FIG. 4 is a schematic view of the module according to one embodiment of the invention.

The present invention is applicable to any type of chip card, and in particular to chip cards including at least two substrates, layers or inlays, each including at least one electronic component. The invention finds use in chip cards that are able to communicate with the outside by contact and/or contactlessly.

It should be noted that in the embodiments described below, the chip card includes two substrates. However, the invention is also applicable to chip cards including more than two substrates.

First, the context to which the invention applies will be presented with reference to FIGS. 1A and 1B.

FIG. 1A shows a security device 1 of the prior art.

The security device is a chip card 1 including a card body 2 and a module 20 that is mounted in the card body 2. The module 20 is formed, in one embodiment, by a contact interface 21 for communication outside the chip card 1, and an integrated circuit (not visible in the figure). The integrated circuit is mounted on an inner face of the contact interface and is electrically connected to the contact interface 21 such that the integrated circuit is able to communicate outside the chip card 1 via the contact interface 21.

It should be noted that the various elements of the chip card 1 are illustrated schematically and that not all of the elements are visible.

The card body 2 shown in FIG. 1A includes two outer layers, only one of which is visible in FIG. 1A, which are generally made of plastic materials. In the illustrated chip card, two substrates, inlays or layers are arranged between the two outer layers.

In the chip card of the prior art shown, the card body 2 includes a first substrate 30 and a second substrate 40 lying in respective parallel planes.

It should be noted that in chip cards, the substrates may be subject to slight deformations as they are being incorporated within the chip card. Thus, in this document, a substrate lying in a plane should be understood as lying substantially in a plane.

In practice, each substrate is comprised between two parallel planes, referred to as “tolerance planes”, which are separated from one another by a given tolerance value. This given tolerance value is so low that it may be assumed that the substrate is lying in a plane.

Furthermore, when reference is made to “parallel planes”, the tolerance planes of one substrate are parallel to the tolerance planes of the other substrate, respectively.

In one embodiment, the first substrate 30 includes an antenna 31. This antenna 31 is formed by conductive wires that are implemented on the first substrate 30 and is connected to the module 20 such that the antenna may be used for the integrated circuit 22 in the module 20 to communicate contactlessly outside the chip card 1.

In the described embodiment, the second substrate 40 includes a flexible printed circuit in which electronic components are mounted. It should be noted that the flexible printed circuit forms the second substrate 40 and that the same numerical reference is used to denote the two elements.

In FIG. 1A, the flexible printed circuit 40 includes in particular a display 41, a microcontroller 42 managing the operation of the display 41, and a battery 43 storing the energy required for the electronic components on this second substrate 40 to operate.

The second substrate 40 further includes an antenna 44, formed by conductive tracks that are implemented on the second substrate 40. This antenna 44 is intended to allow the electronic components on the flexible printed circuit 40 to communicate outside the chip card 1. For example, operations of personalizing the electronic components of the flexible printed circuit 40 that are required for manufacturing the chip card 1 are implemented via this antenna 44.

This antenna 44 may be similar to or different from the antenna 31 of the first antenna substrate or inlay 30.

An interface cavity is formed in an outer layer (not visible in the figure) of the chip card 1, in which the module 20 is housed. The module 20 thus opens out onto an outer face of the card body 2, and is flush with this outer face.

It should be noted that in the chip card 1 shown in FIG. 1A, the integrated circuit of the module 20 is able to communicate outside the chip card 1 by contact through a contact interface 21 or contactlessly through the antenna 31 in the first substrate 30.

The flexible printed circuit 40 is able to communicate outside the chip card 1 contactlessly through its antenna 44.

It should be noted that the first substrate 30 and the second substrate 40 are not connected to one another and that the module 20 is not connected to the flexible printed circuit 40.

FIG. 1B shows a second security device 1′ of the prior art.

This security device 1′ is similar to the security device 1 described with reference to FIG. 1A, the main difference being that the integrated circuit 22′ is not mounted on the contact interface 21′ but on one of the substrates.

In this chip card 1′ of the prior art, the card body 2′ includes a printed circuit substrate 50. Various electronic components, such as the integrated circuit 22′, an electronic interface component 51, such as a fingerprint sensor, a microcontroller 52 managing the acquisition of fingerprints using the fingerprint sensor 51, a battery 53 and an antenna 54 that is connected to the microcontroller 52 are mounted on the substrate 50.

The substrate 50 also includes an antenna 61. The antenna 61 is connected to the integrated circuit 22′ by conductive tracks, such that the antenna 61 may be used for the integrated circuit 22′ to communicate contactlessly.

The substrate 50 further includes a plurality of connectors 70 for connecting the electronic components on the substrate 50 with the contact interface 21′.

FIG. 2A schematically shows a chip card 100 according to a first embodiment of the invention.

The illustrated chip card 100 includes a card body 101 and a contact interface 21 that is mounted in the card body 101.

In this embodiment, an integrated circuit (not visible in the figure) is mounted on an inner face of the contact interface 21. The assembly formed by the contact interface 21 and the integrated circuit is referred to as a module.

The card body 101 includes a first substrate 300 and a second substrate 400 lying in respective parallel planes.

As mentioned above with reference to FIG. 1A, in practice the tolerance planes of one substrate are parallel to the tolerance planes of the other substrate, respectively.

Of course, as mentioned above, the number of substrates in the card body may be greater than two. Thus, in other embodiments (not shown), the card body includes other, additional substrates.

In one embodiment, the first substrate 300 includes an antenna 301 that is dedicated in particular to communication between the module 20 and outside the chip card 100, in particular to communication between the integrated circuit and outside the chip card 100. The second substrate 400 includes a flexible printed circuit on which electronic components are mounted.

The term “electronic component” is understood to mean any electronic component mounted on the substrates that plays a role in the operation of the chip card 100. Thus, the electronic component may be an antenna, an integrated circuit, a microcontroller, a display, a battery, conductive tracks or conductive wires, among others.

The antenna 301 is formed by conductive wires that are implemented on the first substrate 300 and comprises connection areas 300a, which are made of a conductive material. The connection area 300a corresponds to one embodiment of the antenna 301 on the substrate 300 for facilitating the connection thereof with the module 20, in particular with the contact interface 21.

Other embodiments of the antenna 301 are possible for facilitating the connection thereof with the contact interface 21. Thus, in another embodiment, the connection area 300a may include extensions of the conductive wires forming the antenna 301 by forming a plurality of passages in the surface zone of the substrate 300 in which the connection with the contact interface 21 will be made. Of course, any other electronic component may be used for the implementation of the connection area 300a.

These embodiments for the connection between the antenna and the contact interface will not be described further in this document since they are known to a person skilled in the art.

The integrated circuit of the module 20 and certain electronic component of the substrate 400 (such as the battery, the microcontroller, etc.) are not shown in this figure, these electronic components potentially corresponding, for example, to the electronic components described with reference to FIG. 1A.

As described with reference to FIG. 1A, the flexible printed circuit forms the second substrate 400 and the same numerical reference is used to denote the two elements.

The module 20 may be seen in FIG. 3. FIG. 3 schematically illustrates a sectional view of a portion of the chip card 100 in which the module 20 and a portion of the substrates 300, 400 are visible. The module 20 includes a contact interface 21 and an integrated circuit 22.

In this embodiment, the module 20 is located in an interface cavity (not visible in the figure) that is formed in one or more layers including an outer layer 102 of the card body 101 and/or the substrates 300, 400. The contact interface 21 opens out onto an outer face 101a of the card body 101 and an outer face 21e of the contact interface 21 is flush with this outer face 101a of the card body 101.

The contact interface 21 further includes external connection means 21a for communication outside the chip card 100 and internal connection means 21b, 21c for communication inside the chip card 100. The internal connection means 21b, 21c and the integrated circuit 22 are arranged on an inner face of the contact interface 21.

In the embodiment shown, the internal connection means include a first internal connector 21b connecting the contact interface 21 to the first substrate 300, in particular to the antenna 301 of the first substrate 300, via the connection area 300a. The internal connection means further include a second internal connector 21c connecting the contact interface 21 to the second substrate 400, in particular to at least one of the electronic components in the second substrate 400, via an electronic component 400a in the second substrate 400.

Of course, when the card body includes additional substrates, the internal connection means include additional internal connectors for connecting the contact interface to the electronic components in the additional substrates.

In the described embodiment, the electronic component 400a is a conductive track that is formed on the second substrate 400 allowing the contact interface 21 to be connected to an electronic component on the second substrate 400.

Thus, the contact interface 21 is electrically connected to the antenna 301 of the first substrate 300 (via its connection area 300a) and to at least one electronic component of the second substrate 400 (via the electronic component 400a) through the internal connection means 21b, 21c.

It should be noted that only one first internal connector 21b and only one second internal connector 21c are shown in FIG. 3. However, a plurality of connectors could form the first internal connector 21b and/or a plurality of connectors could form the second internal connector 21c.

Furthermore, at least one solder ball 401 connects the second internal connector 21c of the contact interface 21 to the second substrate 400. The dimensions of this at least one solder ball 401 are such that the contact interface 21, in particular the internal connector 21c of the contact interface 21, makes contact with the second substrate 400.

According to some embodiments, said at least one solder ball may be a solder bump, a flex bump or a copper pillar, among others. The size of the solder ball 401 is determined according to the distance between the contact interface 21 and the printed circuit 400 and the dimensions of the internal connection means 21c of the contact interface 21. Furthermore, it is determined by taking the maximum electric current that will pass through this solder ball into account. Also taken into account are the size of the contact area between the solder ball 401 and the internal connector 21c of the contact interface 21 or the anisotropic conductive film, and the effect of the solder ball 401 being squashed during the assembly of the card body 101.

Furthermore, it is determined by taking nominal values and associated tolerance margins for the distances and dimensions of all of the constituent elements of the chip card 100 into account.

By way of nonlimiting example, the solder balls are typically between 200 and 250 μm in size. Of course, these values may differ.

Because of the thickness constraints of chip cards, the substrates 300, 400 are not located facing the entirety of the contact interface 21 and/or of the integrated circuit 22.

Furthermore, as may be seen in FIG. 4, the integrated circuit 22 and the contact interface 21 are electrically connected by electrical wires that are formed on the inner face 21i of the contact interface 21.

When manufacturing the chip card, the superposition of electronic components over these electrical wires connecting the printed circuit 22 to the contact interface 21 is avoided.

In the described embodiment, the second substrate 400 includes a zone of overlap 402 (FIG. 2A) that is arranged facing a portion of the contact interface 21.

Conductive tracks 400a are placed on the zone of overlap 402, the solder balls 401 being placed on the conductive tracks 400a.

In one embodiment, the area of overlap 402 includes drilled holes 403. These drilled holes 403 allow the contact interface 21 and the zone of overlap 402 to adhere better to the card body 101.

The size of the zone of overlap 402 is such that it is able to accept one or more solder balls 401 for connecting the second substrate 400 to the contact interface 21.

The area of the zone of overlap 402 is determined according to the number and the size of the drilled holes 403 and the size and the number of solder balls 401 forming the connection between the contact interface 21 and the electronic component 400a of the second substrate 400.

By way of non limiting example, the area occupied by the set of solder balls 401 is 6.25 mm² and the area of the zone of overlap is 12.5 mm².

For example, the value of the ratio of the area occupied by the set of solder balls 401 to the zone of overlap 402 is between 0.2 and 0.7.

In particular, the zone of overlap 402 is arranged facing the second internal conductor 21c of the contact interface 21.

In this embodiment, and as can be seen in FIG. 3, said at least one solder ball 401 is located between the internal connector 21c of the contact interface 21 and the second substrate 400.

In other embodiments (not shown), the electronic components of additional substrates are also connected to the internal connection means of the contact interface.

For example, in one embodiment, a third substrate is positioned in the same plane as the second substrate, the third and second substrates each having a zone of overlap facing a distinct portion of the internal connection means of the contact interface.

In another embodiment, the third substrate is positioned in a plane that is parallel to the first and second substrates and the solder balls used for connecting the contact interface to the third substrate are thus different in size compared to those used for connecting the contact interface to the second substrate. It should be noted that in this example, the second and third substrates are located different distances away from the contact interface and that the sizes of the solder balls used are matched to the distance to be filled between each substrate and the contact interface.

The embodiments that have been provided, along with the envisaged variants, constitute only possible examples for implementing the invention, which is not limited thereto.

FIG. 4 shows a front view of the inner face 21i of the contact interface 21.

Thus, this figure shows the integrated circuit 22 positioned on a central portion of the contact interface 21. Connectors 210 are arranged on the inner face 21i of the contact interface 21.

A portion of these connectors 210 are used for electrically connecting the integrated circuit 22 to the contact interface 21.

These electrical connections will not be described further in this document since producing a module including a contact interface 21 and an integrated circuit 22 and connections between the contact interface 21 and the integrated circuit 22 is known practice for a person skilled in the art.

In one embodiment, the contact interface 21 includes two internal connectors 21c. The internal connectors 21c correspond to connectors 210 of the contact interface 21, respectively, that have been moved such that the internal connectors 21c are arranged facing the zone of overlap 402 of the second substrate 400.

Thus, the contact interface 21 may be connected to the second substrate 400 easily without running the risk of making unintentional contact with other portions of the contact interface 21.

Returning to FIG. 3, in the described embodiment, anisotropic conductive films 500, 501 are positioned between the inner face 21i of the contact interface 21 and the connection area 300a, and between the inner face 21i of the contact interface 21 and the solder ball 401. In one embodiment, the anisotropic conductive film 500, 501 is an adhesive allowing the contact interface 21 to be mechanically and electrically connected to the first substrate 300 and to the second substrate 400.

Furthermore, the anisotropic conductive film 500, 501 allows the empty space between the various elements be connected in the chip card 100, in particular between the first substrate 300 and the contact interface 21 and between an assembly, formed by the second substrate 400 and the solder ball 401, and the contact interface 21, to be filled.

In other embodiments, a conductive glue may be used instead of the anisotropic conductive film to fill the empty space between the various elements to be connected in the chip card 100, in particular between the first substrate 300 and the contact interface 21 and between the assembly, formed by the second substrate 400 and the solder ball 401, and the contact interface 21.

In one embodiment, and again because of the thickness constraints of chip cards, the second substrate 400 is located in a substrate cavity formed in the first substrate 300. Specifically, since the antenna 301 in the first substrate 300 is located on the periphery of the first substrate 300, the substrate cavity is formed in the central portion of the first substrate 300.

It should be noted that the electronic components that are mounted on the flexible printed circuit 400 have a certain thickness and that superposing both substrates in their entirety would increase the thickness of the chip card.

Furthermore, the superposition of substrates is limited by the electronic components that are located on the various substrates.

Thus, in the described embodiment, the antenna 301 in the first substrate 300 and the electronic components that are located on the flexible printed circuit 400 are not superposed.

Of course, in other embodiments, the antenna in the first substrate 300 and a portion or the entirety of the electronic components that are located on the printed circuit 400 may be superposed.

It should be noted that the components are superposed or otherwise depending on the constraints related to the thickness of the chip card 100.

FIG. 2B schematically shows a chip card 100 according to a second embodiment of the invention.

In the chip card shown in FIG. 2B, certain elements that are placed under opaque layers are shown as visible in order to clarify the description of the various elements of the chip card.

The chip card 100′ includes a card body 101′, the card body 101′ including a first substrate 300′ and a second substrate 400′. The first substrate 300′ and the second substrate 400′ lie in respective parallel planes.

It should be noted that in this embodiment, the integrated circuit 22′ is mounted on the second substrate, while in the embodiment shown in FIG. 2A, the integrated circuit is mounted on the contact interface.

In FIG. 2B, the contact interface is not shown, the reference 21′ representing the position where the interface cavity accepting the contact interface is formed. Thus, in this description, the reference 21′ refers to the contact interface.

In the described embodiment, the first substrate 300′ includes an antenna 301′ that is dedicated to allowing the integrated circuit 22′ to communicate outside the chip card 100′.

In the described embodiment, the second substrate 400′ includes a flexible printed circuit in which electronic components, such as the printed circuit 22′, are mounted.

Other electronic components such as a fingerprint sensor 51, a microcontroller 52 managing the acquisition of fingerprints using the sensor 51, a battery 53 or an antenna 54 allowing certain electronic components to communicate contactlessly outside the chip card 100′ are mounted on the second substrate 400.

Since the first substrate 300′ and the second substrate 400′ are superposed over one another, substrate cavities are formed in the first substrate 300′ in order to house electronic components that are mounted on the second substrate 400′ therein.

Like for the embodiment described with reference to FIG. 2A, the antenna 301′ is formed by conductive wires that are implemented on the first substrate 300′, and the first substrate 300′ includes connection areas 300a′ that are made of a conductive material. These connection areas 300a′ are intended for connecting the antenna 301′ of the first substrate 300′ to the contact interface 21′.

In one embodiment, the connection area 300a′ includes extensions of the conductive wires forming the antenna 301′ forming a plurality of passages in the surface zone of the first substrate 300′ in which the connection with the contact interface 21′ will be made.

Of course, other embodiments are possible for forming the connection between the antenna 301′ in the first substrate 300′ and the contact interface 21′.

The second substrate 400′ includes a zone of overlap 402′ that is arranged facing a portion of the contact interface 21′. Connectors 401′/400a′ that are dedicated to connecting the second substrate 400′ to the contact interface 21′ are formed in this zone of overlap 400′.

The contact interface 21′ and the substrates 300′, 400′ are connected in a manner similar to that described with reference to FIG. 3. It should be noted that FIG. 3 shows the connection between the contact interface 21 and the substrates 300, 400 for the chip card 100 shown in FIG. 2A (an integrated circuit is mounted on the contact interface 21). However, the connection between the contact interface and the substrates 300′, 400′ is similar for the chip card 100′ shown in FIG. 2B.

Thus, solder balls 401′ are positioned on conductive tracks 400a′, these both being placed on the zone of overlap 402′.

Like for the first embodiment, the size of the zone of overlap is such that it is able to accept one or more solder balls 401′ for connecting the second substrate 400′ to the contact interface 21′. In one embodiment, the area of overlap 402′ includes drilled holes 403′. These drilled holes 403′ allow the contact interface 21′ and the zone of overlap 402′ to adhere better to the card body 101′. By way of nonlimiting example, the number of drilled holes 403′ here is nine. The area occupied by the holes is 7 mm², each drilled hole 403′ having a minimum diameter of 500 μm, for example 1 mm.

The area of the zone of overlap 402′ is determined according to the number and the size of the drilled holes 403′ and the size and the number of solder balls 401′ forming the connection between the contact interface 21′ and the electronic component 400a′ of the second substrate 400′.

By way of nonlimiting example, the number of solder balls here is seven, the area occupied by the solder balls is 22 mm² and the area of the zone of overlap is 71.2 mm².

For example, the value of the ratio of the area occupied by the set of solder balls 401′ to the zone of overlap 402′ is between 0.2 and 0.7.

For example, the value of the ratio of the area occupied by the set of drilled holes 403′ to the zone of overlap 402′ is between 0.01 and 0.5.

Like for the embodiments described with reference to FIG. 2A, the body of the security device may include a greater number of substrates, at least one electronic component in the substrates being connected to the contact interface.

When a chip card 100′ such as that shown by FIG. 2B is manufactured, one or more substrate cavities are formed in the first substrate 300′, which cavities are designed to accept a portion of the electronic components that are placed on the second substrate. It should be noted that the electronic components that are placed in the substrate cavities correspond to those whose thickness would increase the thickness of the chip card beyond the given thickness, for example beyond the thickness permitted by the standards.

The first substrate 300, 300′ and the second substrate 400, 400′ are positioned between outer layers 102 of the card body 101, 101′.

Furthermore, an interface cavity is formed in one or more layers including an outer layer 102 of the card body 101, 101′ and/or the substrates 300, 300′, 400, 400′, which cavity is configured to accept the contact interface 21, 21′.

The contact interface 21, 21′ is inserted into the interface cavity such that it is flush with the outer face 101a of the card body 101, 101′.

Before inserting the contact interface 21, 21′ into the interface cavity, the process for manufacturing the chip card 100, 100′ includes, according to one embodiment, positioning an anisotropic conductive film 500 on the first internal connector 21b.

Furthermore, a second anisotropic conductive film 501 is positioned on the second internal connector 21c of the contact interface 21, 21′, and at least one solder ball 401, 401′ is positioned between the second anisotropic conductive film 501 and the flexible printed circuit 400, 400′.

In one embodiment, the second anisotropic conductive film 501 is positioned on the contact interface 21, 21′ and said at least one solder ball 401, 401′ is positioned on the flexible printed circuit 400, 400′ before the flexible printed circuit 400, 400′ and the contact interface 21, 21′ are placed in the card body 101, 101′.

In one embodiment, the first anisotropic conductor 500 and the second anisotropic conductive film 501 form an adhesive ring. In one embodiment in which an integrated circuit 22 is mounted on the inner face 21 i of the contact interface 21, this adhesive ring 500, 501 surrounds the integrated circuit 22.

The manufacturing process described above results in a chip card 100, 100′ according to one embodiment and such as shown in the figures. In this chip card 100, 100′, the first substrate 300, 300′ and the second substrate 400, 400′ are connected to the contact interface 21, 21′, the integrated circuit 22, 22′ and the electronic components on the second substrate 400, 400′ being able to communicate by contact outside the chip card 100, 100′.

1. Security device including a body (101, 101′) and a contact interface (21, 21′) that is mounted in said body (101, 101′), said contact interface (21, 21′) including external connection means (21a) for communication outside said security device (100, 100′) and internal connection means (21b, 21c) for communication inside said security device (100, 100′), said body (101, 101′) including at least a first substrate (300, 300′) and a second substrate (400, 400′) lying in respective parallel planes, and including at least a first electronic component (300a, 300a′, 301, 301′) and a second electronic component, respectively,
wherein said contact interface (21, 21′) is electrically connected to said at least a first electronic component (300a, 300a′, 301, 301′) and a second electronic component (400a, 400a′, 41, 42, 43, 44, 51, 52, 53, 54, 22′) of said at least a first substrate and a second substrate (400, 400′), respectively, by means of said internal connection means (21b, 21c).

2. Security device according to claim 1, wherein said contact interface (21, 21′) includes an outer face (21e) that is flush with an outer face (101a) of said body (101, 101′) and an inner face (21i), said external connection means (21a) of said contact interface (21, 21′) being arranged on said outer face (21e), and said internal connection means (21b, 21c) of said contact interface (21, 21′) being arranged on said inner face (21i).

3. Security device according to claim 2, further comprising an integrated circuit (22) that is mounted on said inner face (21i) of said contact interface (21) and electrically connected to at least a portion of said external (21a) and internal (21b, 21c) connection means of said contact interface (21).

4. Security device according to claim 1, wherein the internal connection means (21b, 21c) include at least a first internal connector (21b) and a second internal connector (21c), said first internal connector (21b) connecting said contact interface (21, 21′) to said first electronic component (300a, 300a′, 301, 301′) of said first substrate (300, 300′), and said second internal connector (21c) connecting said contact interface (21, 21′) to said second electronic component of said second substrate (400, 400′).

5. Security device according to claim 1, further comprising an anisotropic conductive film (500) that is positioned between the inner face (21i) of said contact interface (21, 21′) and said first substrate (300; 300′).

6. Security device according to claim 1, wherein at least said second substrate (400, 400′) includes a zone of overlap (402, 402′) that is arranged facing at least a portion of the internal connection means (21c) of the contact interface (21, 21′).

7. Security device according to claim 6, wherein includes at least one solder ball (401; 401′) connecting said portion of the internal connection means (21c) of said contact interface (21; 21′) to said second electronic component of said second substrate (400; 400′) at said zone of overlap (402; 402′).

8. Security device according to claim 7, further comprising an anisotropic conductive film (501) that is positioned between said portion of the internal connection means (21c) of said contact interface (21; 21′) and said at least one solder ball (401; 401′).

9. Security device according to claim 1, wherein said first substrate (300, 300′) includes at least one substrate cavity into which at least a portion of said second substrate (400, 400′) is inserted.

10. Process for manufacturing a security device including a body (101; 101′) and a contact interface (21; 21′), said body (101; 101′) including at least a first substrate (300; 300′) and a second substrate (400; 400′) lying in respective parallel planes, and including at least a first electronic component (300a, 300a′, 301, 301′) and a second electronic component, respectively, and said contact interface (21, 21′) including external connection means (21a) for communication outside said security device (100, 100′) and internal connection means (21b, 21c) for communication inside said security device (100, 100′), said manufacturing process including:
positioning said first substrate (300; 300′) and said second substrate (400; 400′) between outer layers (102) of said body (101; 101′); and
positioning said contact interface (21; 21′) in said body (101; 101′),
said manufacturing process further comprising implementing an electrical connection from said contact interface (21, 21′) to said at least a first electronic component (300a, 300a′, 301, 301′) and a second electronic component (400a, 400a′, 41, 42, 43, 44, 51, 52, 53, 54, 22′) of said at least a first substrate (300;
300′) and a second substrate (400, 400′), respectively, by means of said internal connection means (21b, 21c).

11. Manufacturing process according to claim 10, further comprising positioning an integrated circuit (22) on an inner face (21i) of said contact interface (21) and electrically connecting said integrated circuit (22) to at least a portion of said external (21a) and internal (21b, 21c) connection means of said contact interface (21′).

12. Manufacturing process according to claim 10, further comprising forming at least one substrate cavity in said first substrate (300; 300′), which cavity is designed to accept at least a portion of said second substrate (400; 400′).

13. Manufacturing process according to claim 10, further comprising forming at least one substrate cavity in said first substrate (300, 300′), which cavity is designed to accept at least one electronic component (400a, 400a′, 41, 42, 43, 44, 51, 52, 53, 54, 22′) of said second substrate (400; 400′).

14. Manufacturing process according to claim 10, wherein before said operation of positioning said second substrate (400;
400′) between the outer layers (102) of said body (101, 101′), said manufacturing process includes positioning at least one solder ball (401; 401′) on said second substrate (400; 400′).

15. Manufacturing process according to claim 14, further comprising positioning an anisotropic conductive film (500, 501) between said contact interface (21; 21′) and said first substrate (300; 300′) and second substrate (400; 400′).

16. The security device according to claim 2, wherein the internal connection means include at least a first internal connector and a second internal connector, said first internal connector connecting said contact interface to said first electronic component of said first substrate, and said second internal connector connecting said contact interface to said second electronic component of said second substrate.

17. The security device according to claim 3, wherein the internal connection means include at least a first internal connector and a second internal connector, said first internal connector connecting said contact interface to said first electronic component of said first substrate, and said second internal connector connecting said contact interface to said second electronic component of said second substrate.

18. Security device according to claim 2, further comprising an anisotropic conductive film that is positioned between the inner face of said contact interface and said first substrate.

19. Security device according to claim 3, further comprising an anisotropic conductive film that is positioned between the inner face of said contact interface and said first substrate.

20. Security device according to claim 4, further comprising an anisotropic conductive film that is positioned between the inner face of said contact interface and said first substrate.
